(19) United States
(12) Patent Application Publication
(10) Pub. No.: US 2009/0170232 A1
(43) Pub. Date: Jul. 2, 2009

(54) METHOD FOR MANUFACTURING IAMGE SENSOR

(76) Inventors: Joon-Ku Yoon, Suwon-si (KR); Sung-Hyok Kim, Hwaseong-si (KR)

Correspondence Address: SHERR & VAUGHN, PLLC, 620 HERNDON PARKWAY, SUITE 200, HERNDON, VA, 20170, US

(21) Appl. No.: 12/344,494

(22) Filed: Dec. 27, 2008

(30) Foreign Application Priority Data
Dec. 27, 2007 (KR) 10-2007-0139449

(51) Int. Cl. H01L 31/18; H01L 21/027; H01L 21/00

(52) U.S. Cl. 438/59; 438/96; 438/98; 257/E21.023; 257/E21.211; 257/E21.09

(57) ABSTRACT

In a method for manufacturing an image sensor, an interlayer insulating layer including a metal line is formed on a semiconductor substrate. A lower electrode layer is formed on the metal line such that the lower electrode is connected with the metal line. A photoresist pattern corresponding to the metal line is formed on the lower electrode layer. The lower electrode layer is etched using the photoresist pattern to form a lower electrode connected with the metal line. The photoresist pattern is stripped using a solvent containing fluorine.

The present application claims priority under 35 U.S.C. § 119 to Korean Patent Application No. 10-2007-0139449 (filed on Dec. 27, 2007), which is hereby incorporated by reference in its entirety.

### BACKGROUND

An image sensor is a semiconductor device that converts an optical image to an electrical signal. Image sensors are generally classified as either a charge coupled device (CCD) image sensor or a complementary metal oxide silicon (CMOS) image sensor (CIS). CMOS image sensors typically include a photo diode and a MOS transistor formed in a unit pixel, and obtain an image by sequentially detecting electrical signals of unit pixels in a switching manner. In a CIS structure, a photo diode region for converting a light signal to an electrical signal, and a transistor for processing the electrical signal are horizontally arranged in a semiconductor substrate.

In a related horizontal type CIS, a photo diode and a transistor are horizontally formed adjacent to each other on a substrate. Therefore, an additional region for forming the photo diode is required, which may decrease the fill factor and limit the sensor's resolution.

### SUMMARY

Embodiments relate to a method for manufacturing an image sensor that can employ a vertically integrated photodiode and remove the residue that may be generated in patterning a chromium (Cr) layer used as a lower electrode. Embodiments relate to a method for manufacturing an image sensor that includes: forming an interlayer insulating layer including a metal line on a semiconductor substrate; forming a lower electrode layer on the metal line such that the lower electrode is connected with the metal line; forming a photoresist pattern corresponding to the metal line on the lower electrode layer; etching the lower electrode layer using the photoresist pattern to form a lower electrode connected with the metal line; and stripping the photoresist pattern using a solvent containing fluorine.

### DRAWINGS

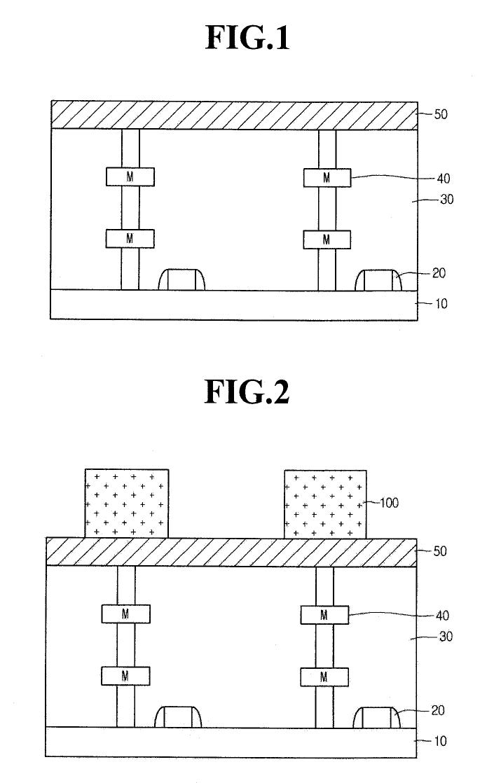

Example FIGS. 1 to 7 are sectional views illustrating a method for manufacturing an image sensor according to embodiments.

### DESCRIPTION

Referring to example FIG. 1, an interlayer insulating layer 30 and an electrically conductive line 40 such as, for example, a metal line may be formed on, or over, a semiconductor substrate 10. The semiconductor substrate 10 may be a single crystal silicon substrate, or may be a substrate doped with a p-type impurity or n-type impurity.

A device isolation layer defining an active region and a field region may be formed in the semiconductor substrate 10. Also, circuitry 20 that may, for example, include a transfer transistor, a reset transistor, a drive transistor and a select transistor, which are connected with a photo diode to convert received photocharges to an electrical signal, may be formed in each pixel on the active region. For example, the circuitry 20 may be any one of 3Tr, 4Tr and 5Tr structures.

The interlayer insulating layer 20 and the metal line 40 may be formed on, or over, the semiconductor substrate 10 so as to connect the circuitry 20 with a power line or a signal line. The metal line 40 and the interlayer insulating layer 30 may be formed in a multi-layer structure. The metal line 40 on, or over, the semiconductor substrate 10 may be formed per unit pixel to connect the circuitry 20 with a photo diode 60. Accordingly, the metal line 40 can deliver the photocharges of the photo diode 60.

The metal line 40 may include an interconnection line M and a plug and may be formed of various conductive materials including metals, alloys or salicides. For example, the metal line 40 may be formed of aluminum (Al), copper (Cu), cobalt (Co), or tungsten (W). According to embodiments, the plug of the metal line 40 may be exposed from a surface of the interlayer insulating layer 30. The metal line 40 may deliver electrons generated in the photo diode to the circuitry 20 of the semiconductor substrate 10, and may be formed per unit pixel such that the metal line 40 may be connected with an impurity doped region formed in the semiconductor substrate 10.

A lower electrode layer 50 may be formed on, or over, the interlayer insulating layer 30 including the metal line 40. For example, the lower electrode layer 50 may be formed of chromium (Cr). Since the lower electrode layer 50 may be formed on, or over, the entire surface of the interlayer insulating layer 30, the lower electrode layer 50 may be electrically connected with the metal line 40.

Referring to example FIG. 2, a photoresist pattern 100 may be formed on, or over, the lower electrode layer 50. The photoresist pattern 100 may be formed, for example, by spin-coating a photoresist film onto the interlayer insulating layer 30 and exposing and developing the photoresist film using a mask. The photoresist pattern 100 may be formed so as to cover the lower electrode layer 50 corresponding to the metal line 40 and expose the remaining region.

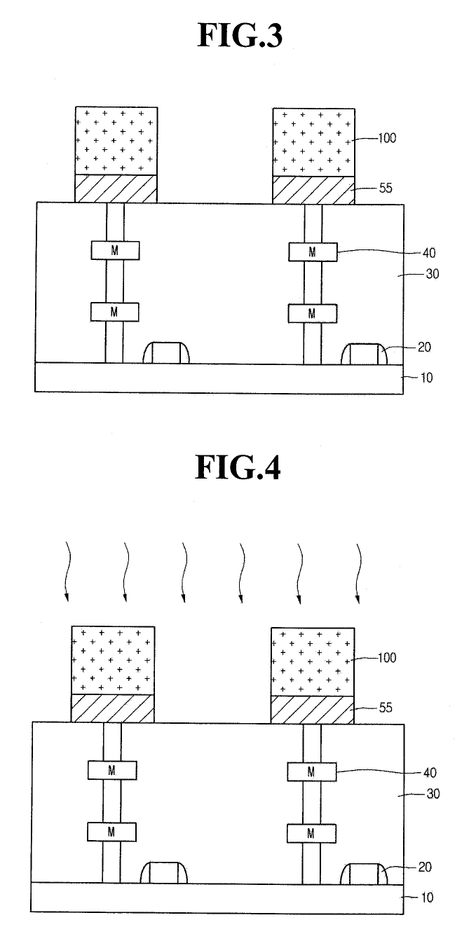

Referring to example FIG. 3, a lower electrode 55 may be formed such that the lower electrode is electrically connected with the metal line 40. The lower electrode 55 may be connected with the metal line 40 and separated per unit pixel. The lower electrode 55 may be formed by etching the lower electrode layer 50 using the photoresist pattern 100 as an etch mask. By the etching, the lower electrode 55 may be formed on, or over, the interlayer insulating layer 30 corresponding to the metal line 40, and the remaining region of the interlayer insulating layer 30 may be exposed.

Referring to example FIG. 4, a strip process for the photoresist pattern 100 may be performed. The strip process for the photoresist pattern 100 may be performed using a solvent containing fluorine. For example, the solvent may be ammonium fluoride, dimethyl acetamide, ammonium acetamide and NE14 comprised of deionized water (DIW). The strip process for the photoresist pattern 100 is generally performed using O₂ gas. O₂ gas can react with Cr to remove the lower electrode 55 formed of Cr together with the photoresist pattern 100. Accordingly, in order to remove only the photoresist pattern 100 on the lower electrode 55, it is beneficial to perform a wet etch using a chemical solution not containing oxygen. According to embodiments, the photoresist pattern 100 on the lower electrode 55 formed of Cr may be lifted off using NE14. By doing so, the photoresist pattern 100 may be removed without damaging the lower electrode 55. Additionally, the strip process for the photoresist pattern 100 may be performed using a different kind of amine-based solvent as well as an amine-based solvent containing NE14.

Even if the photoresist pattern 100 is detached from the lower electrode 55 by the solvent using NE14, the photoresist pattern 100 may not be completely dissolved but may be attached as a polymer 110 on, or over, the semiconductor substrate 10 or the interlayer insulating layer 30.

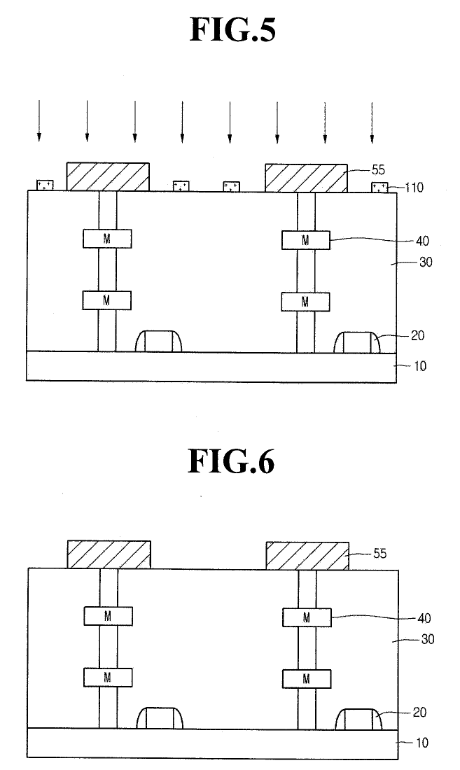

Referring to example FIGS. 5 and 6, the polymer 110 on, or over, the semiconductor substrate 10 including the lower electrode 55 may be removed. The polymer 110 may be removed by a jet scrubber process, for example. Because a jet scrubber process supplies substantially pure water onto the semiconductor substrate 10, it is possible to remove only the lifted-off polymer 110 from the semiconductor substrate 10. By doing so, the lower electrode 55 connected with the metal line 40 may be formed per unit pixel on the interlayer insulating layer 30 as shown in example FIG. 6.

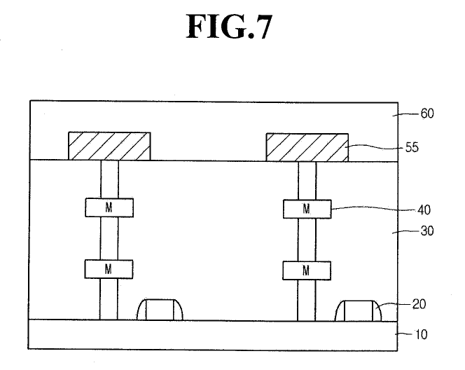

Referring to example FIG. 7, a photo diode 60 may be formed on, or over, the semiconductor substrate 10 including the lower electrode 55. For example, the photo diode 60 may be formed by implanting an n-type or p-type impurity into a crystalline semiconductor layer and then bonding the crystalline semiconductor layer on, or over, the semiconductor substrate 10.

Alternatively, the photo diode 60 may be formed by depositing an amorphous silicon layer on, or over, the interlayer insulating layer 30. That is, the photo diode may be a PIN diode which may include an n-type amorphous silicon layer, an intrinsic amorphous silicon layer, and a p-type amorphous silicon layer. The PIN diode is a photo diode having a junction structure in which the intrinsic amorphous silicon layer is disposed between the p-type amorphous silicon layer and the n-type amorphous silicon layer. A depletion layer formed between the p-type amorphous silicon layer and the n-type amorphous silicon layer is all included in the intrinsic semiconductor layer. The thicker the depletion layer, the more advantageous it is for the depletion layer to generate and hold charges. Accordingly, manufacturing a photo diode having a desired quality may be accomplished by adjusting the thickness of the intrinsic semiconductor layer. Also, an upper electrode, a color filter and a microlens may be further formed on the photo diode 60.

In the method for manufacturing an image sensor according to embodiments, a photo diode is formed on a semiconductor substrate including a metal line, which may be vertically integrated and, because the photo diode may be formed on the semiconductor substrate, the focus length of the photo diode can be shortened to enhance the fill factor. Furthermore, additional on-chip circuitry can be integrated that may maximize the performance of the image sensor, minimize the device size, and minimize manufacturing costs.

In addition, because the photoresist pattern for patterning the lower electrode may be removed by a solvent, the lower electrode, which may be formed of Cr, for example, can be prevented from being damaged. Moreover, because the photoresist pattern can be removed by a solvent and then a residual polymer can be removed by a scrubber process, substantially the entire photoresist pattern may be removed from the semiconductor substrate.

It will be obvious and apparent to those skilled in the art that various modifications and variations can be made in the embodiments disclosed. Thus, it is intended that the disclosed embodiments cover the obvious and apparent the modifications and variations, provided that they are within the scope of the appended claims and their equivalents.

What is claimed is:

1. A method for manufacturing an image sensor comprising:
forming an interlayer insulating layer including an electrically conductive line over a semiconductor substrate;
forming a lower electrode layer over the electrically conductive line such that the lower electrode is electrically coupled with the electrically conductive line;
forming a photoresist pattern corresponding to the electrically conductive line on the lower electrode layer;
etching the lower electrode layer using the photoresist pattern to form a lower electrode electrically coupled with the electrically conductive line; and
stripping the photoresist pattern using a solvent containing fluorine.

2. The method of claim 1, wherein the lower electrode layer comprises chromium.

3. The method of claim 1, comprising:
performing a jet-scrubber process after stripping of the photoresist pattern.

4. The method of claim 3, wherein performing the jet-scrubber process comprises supplying deionized water.

5. The method of claim 1, wherein the solvent comprises one or more of: ammonium fluoride, dimethyl acetamide, ammonium acetamide, and NE14 comprised of deionized water.

6. The method of claim 1, comprising:
forming a photo diode over the interlayer insulating layer including the lower electrode.

7. The method of claim 6, wherein the photodiode comprises a PIN diode.

8. The method of claim 6, wherein forming the photo diode includes:
depositing an n-type amorphous silicon layer, an intrinsic amorphous silicon layer and a p-type amorphous silicon layer over at least a portion of the interlayer insulating layer over which the lower electrode is formed.

9. The method of claim 6, wherein forming the photo diode includes:
implanting an N-type or P-type impurity ion into a crystalline semiconductor layer; and
bonding the crystalline semiconductor layer to the interlayer insulating layer.

10. The method of claim 6, comprising:
forming circuitry including a transistor over the semiconductor substrate.

11. The method of claim 10, wherein the electrically conductive line electrically couples the photo diode with the circuitry.

12. The method of claim 11, wherein the electrically conductive line electrically couples the lower electrode with the circuitry.

13. The method of claim 1, wherein the photoresist pattern is stripped by an amine-based solvent.

14. The method of claim 1, wherein the electrically conductive line is comprised of one of a metal, and alloy, and a salicide.

15. The method of claim 1, wherein the electrically conductive line comprises a metal line.

16. The method of claim 15, wherein the metal line is comprised of one of aluminum, copper, cobalt, and tungsten.

17. The method of claim 1, comprising:
forming circuitry including a transistor over the semiconductor substrate.

18. The method of claim 17, wherein the electrically conductive line electrically couples the lower electrode with the circuitry.

19. The method of claim 1, wherein at least a portion of the electrically conductive line is exposed through a top surface of the interlayer insulating layer.

20. The method of claim 1, wherein forming the photoresist pattern includes:
spin coating a photoresist film over the interlayer insulating layer.
